(19) United States
(12) Patent Application Publication
(10) Pub. No.: US 2004/0164881 A1
(43) Pub. Date: Aug. 26, 2004

(54) Mouth activated input device for an electronically responsive device

(75) Inventors: Kelvin Kwong Loun Mok, Edmonton (CA); Peng Fong Mok, Durham, NC (US); Alfred Ruefli, Sherwood Park (CA); Mark Vernon Fedorak, St. Albert (CA); Edmond Hok Ming Lou, Edmonton (CA); Chris Kirchen, Sherwood Park (CA)

Correspondence Address: CHRISTENSEN, O'CONNOR, JOHNSON, KINDNESS, PLLC, 1420 FIFTH AVENUE, SUITE 2800, SEATTLE, WA, 98101-2347, US

(73) Assignees: Kelvin Kwong Loun Mok; Peng Fong Mok

(21) Appl. No.: 10/782,053

(22) Filed: Feb. 19, 2004

(30) Foreign Application Priority Data
Feb. 21, 2003 (CA) 2,419,655

(51) Int. Cl. H03M 11/00; H03K 17/94

(52) U.S. Cl. 341/20

(57) ABSTRACT

A mouth activated input device includes an elongated tubular body having an exterior surface, a first end and a second end. A first portion of the body at the first end has a first axis. A second portion of the body at the second end has a second axis, which is inclined at an angle to the first axis. A tongue activated multi-directional sensor element is positioned on the second portion. Either a bite switch, a sip and puff switch or both are incorporated into the body.

### FIELD OF THE INVENTION

The present invention relates to a mouth activated input device for use with an electronically responsive device.

### BACKGROUND OF THE INVENTION

A number of mouth activated input devices have been developed to address the needs of people with disabilities. An Example of such a device is U.S. Pat. No. 6,224,524 (Salem et al 2001). There is a need for such mouth activated input devices for use by people with disabilities in manipulating the many electronically responsive devices in their living environment. This includes computers, lights, televisions, video players, audio players, and the like.

### SUMMARY OF THE INVENTION

What is required is a more versatile mouth activated input device.

According to the present invention there is provided a mouth activated input device which includes an elongated tubular body having an exterior surface, a first end and a second end. A first portion of the body at the first end has a first axis. A second portion of the body at the second end has a second axis which is inclined at an angle to the first axis. A tongue activated multi-directional sensor element is positioned on the second portion. Either a bite switch, a sip and puff switch or both are incorporated into the body.

The mouth activated input device, as described above, is designed to provide maximum comfort to the user with maximum functionality. The comfort is provided by the elongated body which has a “bend” forming the first portion with the first axis, the second portion with the second axis and the tongue activated multi-directional sensor element being positioned on the second portion. Functionality is achieved by the combination of the tongue activated multi-directional sensor element in combination with one or more switches. The tongue activated multi-directional sensor element is capable of controlling such things as computer cursor movement. Either a bite switch, a sip and puff switch or both are used to make selections. It is preferred that both the bite switch and the sip and puff switch be provided to give maximum flexibility and functionality. Although the primary market for this device is perceived to be for persons with disabilities, it will be understood that the device will also be useful to persons, such as helicopter pilots or crane operators, who may wish to use this device when their hands are occupied with other tasks.

Although beneficial results may be obtained through the use of the mouth activated input device, as described above, should the device go too far into the user's mouth it could cause choking or respiratory distress. Even more beneficial results may, therefore, be obtained when a guard extends from the exterior surface on the first portion which is adapted to limit the extent to which the body can be inserted into a person's mouth.

Although beneficial results may be obtained through the use of the mouth activated input device, as described above, users come in a variety of sizes. Even more beneficial results may, therefore be obtained when the guard is a locking sleeve which has more than one locking position. This enables the guard to be axially adjustable by selecting one of the locking positions along the first portion of the tubular body.

Although beneficial results may be obtained through the use of the mouth activated input device, as described above, even more beneficial results may be obtained when the sip and puff switch has an elongated opening which extends axially along the body. The elongated opening is designed to prevent the user from accidentally blocking access to the sip and puff switch.

Although beneficial results may be obtained through the use of the mouth activated device, as described above, even more beneficial results may be obtained when the sip and puff switch has a saliva trap chamber with a removable cover to facilitate cleaning.

Although beneficial results may be obtained through the use of the mouth activated input device, as described above, beneficial results have been obtained through the use of a multi-directional tongue activated sensor element in the form of a sensor element plate which pivots to four primary positions and any positions in between about two substantially perpendicular intersecting pivot axes.

### BRIEF DESCRIPTION OF THE DRAWINGS

These and other features of the invention will become more apparent from the following description in which reference is made to the appended drawings, the drawings are for the purpose of illustration only and are not intended to in any way limit the scope of the invention to the particular embodiment or embodiments shown, wherein:

FIG. 1 is a bottom perspective view of a mouth activated input device constructed in accordance with the teachings of the present invention.

FIG. 2 is a top perspective view of the mouth activated input device illustrated in FIG. 1.

FIG. 3 is a side elevation view, in section, of the mouth activated input device illustrated in FIG. 1.

FIG. 4 is a perspective view in partial section, of the mouth activated input device illustrated in FIG. 1.

FIG. 5 is a perspective view of internal components of the mouth activated input device illustrated in FIG. 1.

FIG. 6 is a detailed side elevation view, in section, of the tongue activated sensor element plate of the mouth activated input device illustrated in FIG. 1.

FIG. 7 is a perspective view of the tongue activated sensor element plate of the mouth activated input device illustrated in FIG. 1.

FIG. 8 is a perspective view in partial section of the tongue activated sensor element plate of the mouth activated input device.

### DETAILED DESCRIPTION OF THE PREFERRED EMBODIMENT

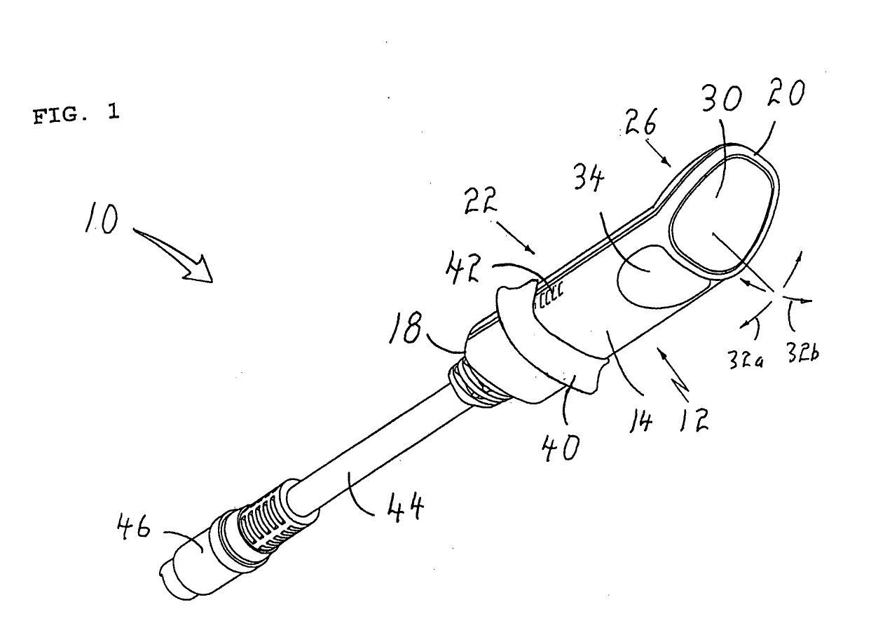

The preferred embodiment, a mouth activated input device generally identified by reference numeral 10, will now be described with reference to FIGS. 1 through 6.

Structure and Relationship of Parts:

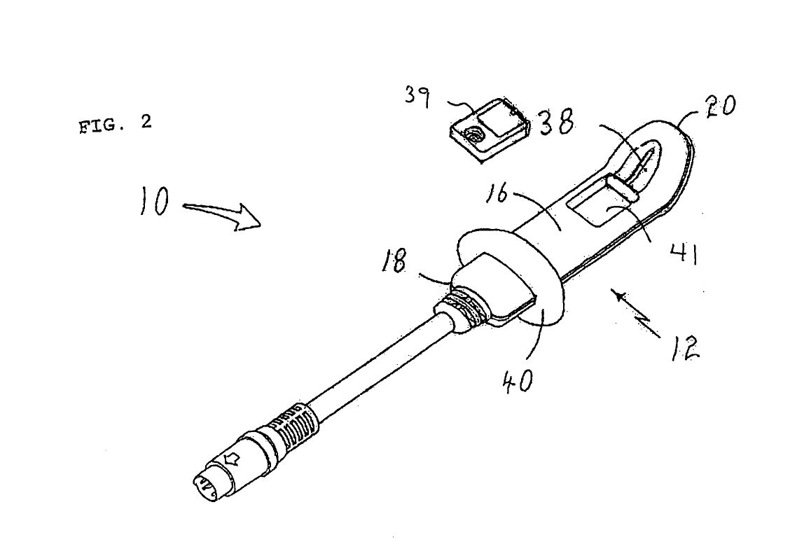

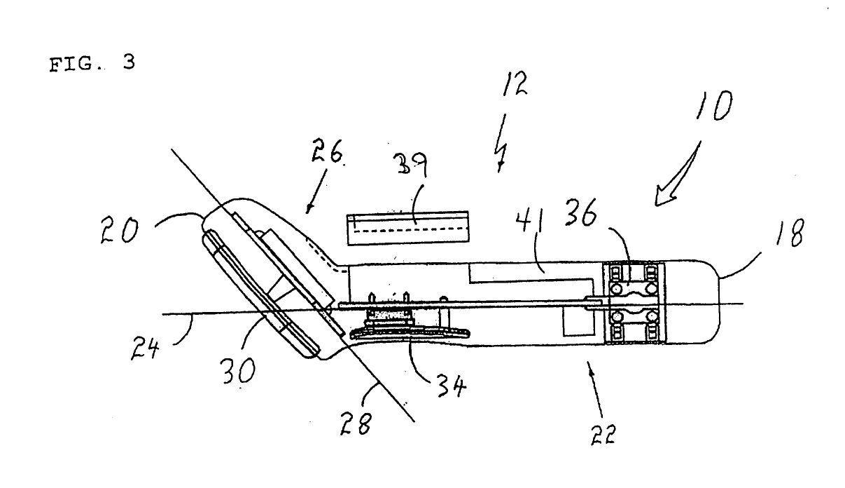

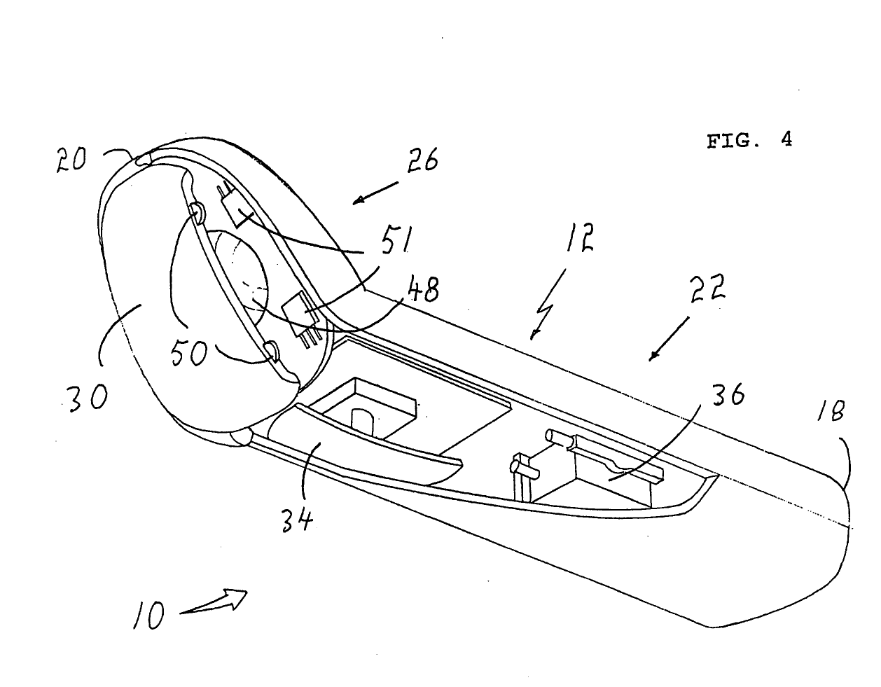

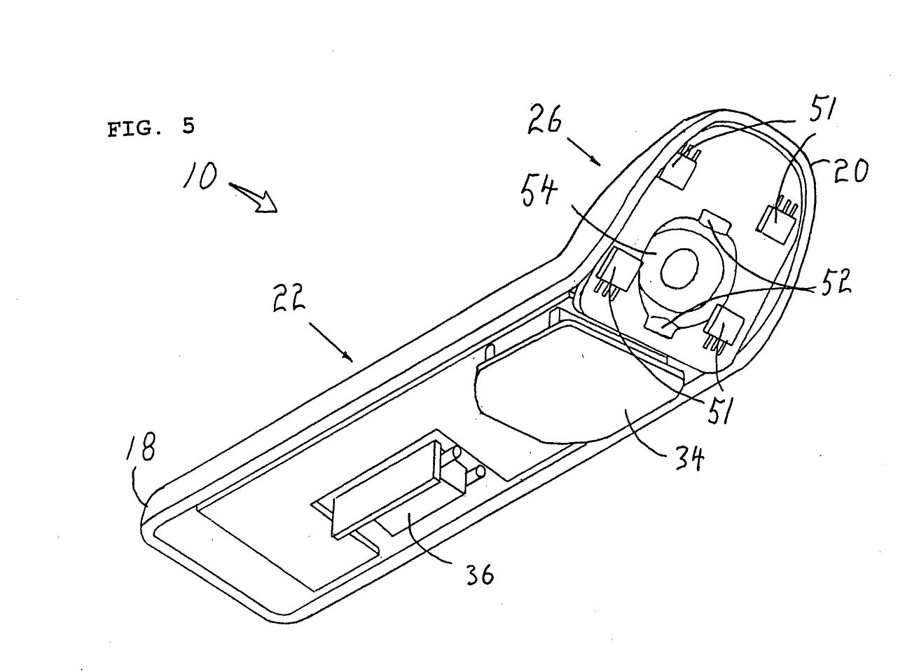

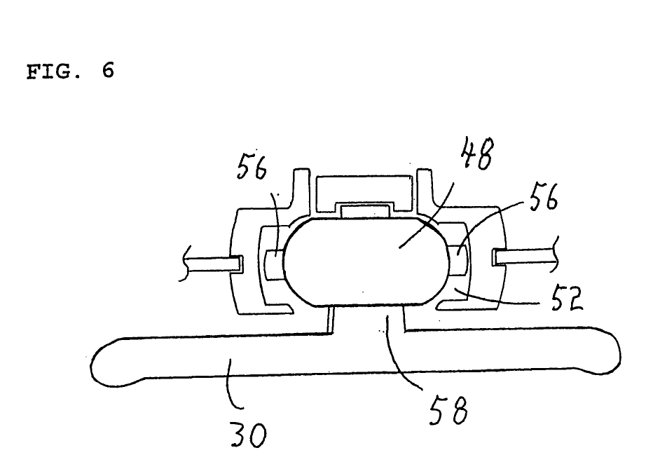

Referring to FIG. 1, mouth activated input device 10 includes an elongated tubular body 12 having a first end 18 and a second end 20. Tubular body 12 has a lower exterior surface 14. Referring to FIG. 2, tubular body 12 has an upper exterior surface 16. Referring to FIG. 3, tubular body 12 has a first portion 22 at first end 18 with a first axis 24. Tubular body 12 also has a second portion 26 at second end 20 with a second axis 28. Second axis 28 is inclined at an angle to first axis 24. Referring to FIG. 1, second portion 26 is adapted with a tongue activated sensor element plate 30 which is positioned on lower exterior surface 14. Tongue activated sensor element plate 30 pivots in combination to four primary positions and any positions in between about two substantially perpendicular axes 32a and 32b. First portion 22 is adapted with a force sensitive bite switch 34 which is also positioned on lower exterior surface 14. Referring to FIG. 4, elongated tubular body 12 is adapted with a sip and puff switch 36. Referring to FIG. 2, an elongated opening or sip and puff groove 38 extends axially along upper exterior surface 16. A saliva trap cover 39 covers a saliva trap chamber 41 that connects sip and puff groove 38 to sip and puff switch 36. Referring to FIG. 1, elongated tubular body 12 has a guard 40 which extends from lower exterior surface 14 as well as upper exterior surface 16 as shown in FIG. 2. Guard 40 is adapted to limit the extent to which elongated tubular body 12 can be inserted into a person's mouth. Referring to FIG. 1, in the illustrated embodiment, guard 40 is in the form of a locking sleeve with adjustable positions 42. Mouth activated device 10 has a cable connection 44 and a fitting 46 adapted to input data into an electronically responsive device. Referring to FIG. 4, tongue activated sensor element plate 30 is mounted on a multi-directional gimbal 48. Tongue activated sensor element plate 30 is adapted with magnets 50 which are spaced in relation to “Hall effect” sensors 51. Referring to FIG. 5, internal components of tongue activated sensor element plate 30 (as shown in FIG. 4), bite switch 34 and sip and puff switch 36 are illustrated. Second portion 26 is further adapted with gimbal slots 52 and ring bumper 54. Referring to FIG. 6, in the illustrated embodiment, multi-directional gimbal 48 has two nubs 56 adapted to move within gimbal slots 52. Tongue activated sensor element plate 30 is adapted with a tapered and keyed shaft 58 which is inserted into multi-directional gimbal 48.

Referring to FIG. 4, although tongue activated multi-directional sensor element is described as using magnets 50 and sensors 51, it will be immediately apparent that other technologies can be used. This sensor element can use any element capable of detecting a signal that includes, but is not restricted to, an electrical, magnetic, radio frequency, light-responsive, pressure responsive or sound frequency source. This can take the form of, but is not restricted to, switches, sensors and transducers.

Operation:

The use and operation of mouth activated input device 10 will now be described with reference to FIGS. 1 through 6. Referring to FIG. 11 mouth activated input device 10 is connected to an electronically responsive device by cable connection 44 and fitting 46. Guard 40 may be adjusted for individual physiology by selectively snapping it in place at any one of adjustable positions 42. Upon insertion into the mouth, a person may actuate tongue activated sensor element plate 30 by changing its orientation along one or both of perpendicular axes 32a or 32b. Plate 30 may be inclined toward any of four primary positions and any secondary positions in between. When tongue activated sensor element plate 30 is manipulated in this way, any one of magnets 50 will be re-oriented closer to any one of Hall effect sensors 51 illustrated in FIGS. 4 and 5. The combination of changes in proximity between magnets 50 and Hall effect sensors 51 is translated as a signal that is transmitted through cable connection 44 to an electronically responsive device. For example, the multi-directional capability of multi-directional gimbal 48 illustrated in FIGS. 4 and 6, would translate into the same kind of multi-directional movement required to operate a cursor in a computer. In a similar fashion, a person can actuate bite switch 34 and sip and puff switch 36 to click and select items in a computer. Due to first axis 24 being inclined at an angle to second axis 28, mouth activated input device 10 is operated with optimal comfort.

Variation:

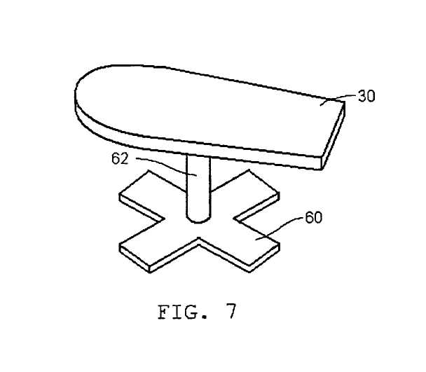

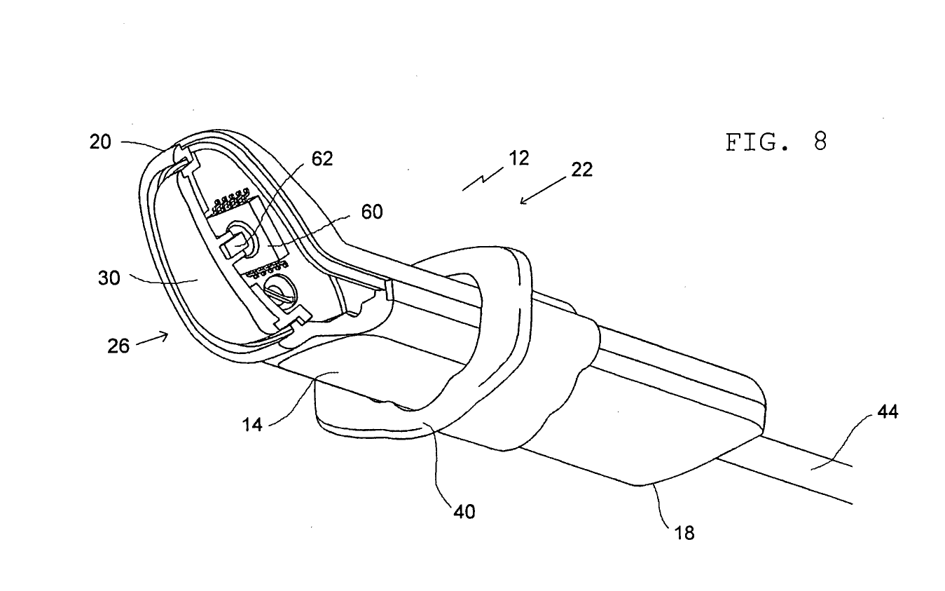

A variation will now be discussed with reference to FIGS. 7 and 8.

Instead of detecting movement using sensors 51, a strain gauge 60 such as that shown in FIG. 7 can be employed. Strain gauge 60 is capable of detecting movement in two dimensions, such that it is an adequate replacement for sensor 51. It is located at the bottom of a post 62, such that, as post 62 is moved, strain gauge 60 detects the movement and reacts as did sensor 51. While FIG. 7 shows a detailed view of the variation, FIG. 8 shows the device incorporating the variation.

In this patent document, the word “comprising” is used in its non-limiting sense to mean that items following the word are included, but items not specifically mentioned are not excluded. A reference to an element by the indefinite article “a” does not exclude the possibility that more than one of the element is present, unless the context clearly requires that there be one and only one of the elements.

It will be apparent to one skilled in the art that modifications may be made to the illustrated embodiment without departing from the spirit and scope of the invention as hereinafter defined in the claims.

The embodiments of the invention in which an exclusive property or privilege is claimed are defined as follows:

1. A mouth activated input device, comprising:
an elongated tubular body having an exterior surface, a first end and a second end, with a first portion at the first end having a first axis and a second portion at the second end having a second axis which is inclined at an angle to the first axis;
a tongue activated multi-directional sensor element positioned on the second portion; and
at least one of a bite switch or a sip and puff switch incorporated into the body.

2. The mouth activated input device as defined in claim 1, wherein a guard extends from the exterior surface on the first portion which is adapted to limit the extent to which the body can be inserted into a person's mouth.

3. The mouth activated input device as defined in claim 2, wherein the guard is a locking sleeve which has more than one locking position, such that the guard is axially adjustable to a selected one of the locking positions along the first portion of the tubular body.

4. The mouth activated input device as defined in claim 1, wherein there is provided both the bite switch and the sip and puff switch.

5. The mouth activated input device as defined in claim 1, wherein the sip and puff switch has an elongated opening, which extends axially along the body.

6. The mouth activated input device as defined in claim 1, wherein the sip and puff switch has a saliva trap chamber with a removable cover to facilitate cleaning.

7. The mouth activated input device as defined in claim 1, wherein the tongue activated multi-directional sensor element is in the form of a pivoting plate.

8. The mouth activated input device as defined in claim 7, wherein the plate pivots to four primary positions about two substantially perpendicular intersecting pivot axes.

9. The mouth activated input device as defined in claim 8, wherein the plate pivots to secondary positions between the four primary positions.

10. A mouth activated input device, comprising:
an elongated tubular body having an upper exterior surface, a lower exterior surface, a first end and a second end, with a first portion at the first end having a first axis and a second portion at the second end having a second axis which is inclined at an angle to the first axis;
a tongue activated sensor element plate positioned on the lower exterior surface of the second portion of the body, sensor element plate pivoting to four primary positions about two substantially perpendicular intersecting pivot axes; and
a bite switch positioned on the upper exterior surface of the first portion of the body;
a sip and puff switch incorporated into the body, with an elongated opening which extends axially along the upper exterior surface of the body; and
a guard extending from the exterior surface on the first portion of the body which is adapted to limit the extent to which the body can be inserted into a person's mouth.

11. The mouth activated input device as defined in claim 10, wherein the guard is a locking sleeve which has more than one locking position, such that the guard is axially adjustable to a selected one of the locking positions along the first portion of the body.

12. The mouth activated input device as defined in claim 10, wherein the sip and puff switch has a saliva trap chamber with a removable cover to facilitate cleaning.

13. The mouth activated input device as defined in claim 10, wherein the sensor element plate pivoting to secondary positions between the four primary positions.
